(19) United States
(12) Patent Application Publication
(10) Pub. No.: US 2014/0083615 A1
(43) Pub. Date: Mar. 27, 2014

(54) ANTENNA ASSEMBLY AND A PLASMA PROCESSING CHAMBER HAVING THE SAME

(71) Applicant: GEN CO., LTD., Gyeonggi-do (KR)

(72) Inventors: Gyoo-Dong KIM, Gyeonggi-do (KR); Sung-Yong KANG, Gyeonggi-do (KR)

(73) Assignee: GEN CO., LTD., Gyeonggi-do (KR)

(21) Appl. No.: 13/828,227

(22) Filed: Mar. 14, 2013

(30) Foreign Application Priority Data
Sep. 25, 2012 (KR) 10-2012-0106822

(51) Int. Cl. H01J 37/32

(52) U.S. Cl. CPC H01J 37/3211
USPC 156/345.37

(57) ABSTRACT

A plasma processing chamber includes a chamber body having a substrate support on which the substrate to be processed is placed, a dielectric window forming a ceiling of the chamber body, an inductive antenna set on a upper part of the dielectric window and configured to supply an electromotive force generating plasmas into the chamber body, a cooling water supplier configured to supply cooling water into the inductive antenna, a heating plate set on a upper part of the inductive antenna, and a heat conductive member filled in a space between the heating plate and the dielectric window to contact the heating plate, the inductive antenna and the dielectric window, wherein the heat conductive member makes the dielectric window to have a uniform heat distribution through the heat conduction between the inductive antenna and the dielectric window, and the heat conduction between the heating plate and the dielectric window.

### CROSS-REFERENCE TO RELATED APPLICATION

This application claims priority of Korean patent application numbers 10-2012-0106822 filed on Sep. 25, 2012. The disclosure of each of the foregoing applications is incorporated herein by reference in its entirety.

### FIELD OF THE INVENTION

The present invention relates to a plasma processing chamber, and more particularly, to a plasma processing chamber equipped with an antenna assembly comprising a heating plate and a heat conductive member for constant temperature control.

### BACKGROUND OF THE INVENTION

Plasma is a highly ionized gas containing an approximately equal number of positive ions and electrons. Plasma discharge is used for gas excitation to generate an active gas comprising ions, free radicals and molecules. An active gas is widely used in various fields. An active gas is generally used in semiconductor fabrication processes, for example, such as etching, deposition, cleaning, asking and the like.

Types of plasma sources for generating plasma are diverse. Typical examples of plasma sources include capacitively coupled plasmas using radio frequency and inductively coupled plasma. A capacitively coupled plasma source has an advantage in that processing productivity is high compared with the other plasma sources because the capability of accurately controlling capacitive coupling and ions is excellent. An inductively coupled plasma source can increase ion density with increasing radio frequency power, and thereby ion bombardment is relatively low, such that it is suited for accomplishing high density plasmas. Therefore, an inductively coupled plasma source is generally used to obtain high density plasmas.

Radio frequency antenna is generally used as spiral type antenna or cylinder type antenna. Radio frequency antenna is disposed outside a plasma processing chamber, and transfers induced electromotive force into the plasma processing chamber through a dielectric window, such as quartz.

In the semiconductor fabrication industry, more improved plasma processing technologies are required as semiconductor devices are super-miniaturized, silicon wafer substrates to fabricate semiconductor circuits become large, glass substrates to manufacture liquid crystal displays become large and new materials to be processed are developed. Further, new technologies, such as “Through Silicon Via” (TSY), may be applied to overcome the limits of integrity.

On the other hand, dielectric window forming a ceiling on a upper part of the chamber body and an inductive antenna thereon are installed in a plasma processing chamber constituting an inductively coupled plasma source. When the inductive antenna is operated in substrate treatment process, induced electromotive force will be transferred to the chamber body. When plasma is formed in the chamber body, the dielectric window will be heated. Cooling water is supplied to the inductive antenna which is a typical hollow form to prevent overheating of the dielectric window.

However, when local heat is generated during heating of the dielectric window, cracks may be formed due to disuniform temperature differences, and the dielectric window may be broken due to in-out pressure differences.

When the substrate treatment process is completed, plasmas are switched off and substrate replacement process runs, wherein the dielectric window is cooled. In this case, disuniform temperature drops are also problematic. Further, when cooling the dielectric window, polymers may be deposited onto the surface of the dielectric window. In its subsequent process, they may act as particles, and therefore may deteriorate substrate treatment efficiencies.

As the substrates to be treated become large, the dielectric window for inductively coupled plasma source also becomes large. Consequently, the larger dielectric window should be supported more effectively and strongly. Further, higher substrate treatment uniformity is required in the middle area and the outer area of the substrates to be treated. In the semiconductor fabrication process, the maintenance of the production equipment is one of the important factors. The means for supplying processing gases into plasma processing chamber is a gas nozzle. This gas nozzle is directly exposed to plasmas in the chamber body. In this connection, a periodic replacement of the gas nozzle is required. Accordingly, a demand has existed for reducing time for gas nozzle replacement that helps the process productivity improvement.

### SUMMARY OF THE INVENTION

It is an object of the present invention to provide an antenna assembly and a plasma processing chamber comprising the same, which can maintain the constant temperature of a dielectric window during the repetitive substrate treatment process and substrate replacement process in a plasma processing chamber comprising inductively coupled plasma sources, and thereby increase the substrate treatment efficiencies.

It is another object of the present invention to provide an antenna assembly and a plasma processing chamber including the same, which can support a dielectric window more effectively and strongly, and improve the maintenance of a gas nozzle in a plasma processing chamber including inductively coupled plasma sources.

One aspect of the present invention is an antenna assembly and a plasma processing chamber comprising the same. A plasma chamber according to one illustrative embodiment of the present invention includes a chamber body having a substrate support on which a substrate is placed, a dielectric window forming a ceiling of the chamber body, an inductive antenna set on a upper part of the dielectric window and configured to supply an electromotive force generating plasmas into the chamber body, a cooling water supplier configured to supply cooling water into the inductive antenna, a heating plate set on a upper part of the inductive antenna, and a heat conductive member filled in a space between the heating plate and the dielectric window to contact the heating plate, the inductive antenna and the dielectric window, wherein the heat conductive member makes the dielectric window to have uniform heat distribution through the heat conduction between the inductive antenna and the dielectric window, and the heat conduction between the heating plate and the dielectric window.

According to one illustrative embodiment of the present invention, the heat conductive member includes thermal conductive silicon.

According to another illustrative embodiment of the present invention, it further includes an opening which is set in the middle part of the dielectric window to supply gases into the chamber body, a gas manifold which is arranged at an opening in the upper part of the dielectric window; and a tope nozzle engaged with the gas manifold through the opening.

According to still another illustrative embodiment of the present invention, the top nozzle includes a plurality of middle spray holes spraying gases toward the middle area of the substrate support, and a plurality of outer spray holes spraying gases toward the outer area of the substrate support, and the gas manifold and the top nozzle includes a first gas channel connected to the plurality of middle spray holes and a second gas channel connected to the plurality of outer spray holes.

According to still another illustrative embodiment of the present invention, it further includes at least one metal ring gasket which is set on a contact site of the gas manifold and the top nozzle.

According to still another illustrative embodiment of the present invention, the top nozzle includes screw threads for coupling with the gas manifold.

According to still another illustrative embodiment of the present invention, it includes a side ring for supporting the dielectric window in a upper part of the chamber body, and the side ring comprises a tilted support surface inclined outward from the neighboring dielectric window.

According to still another illustrative embodiment of the present invention, the plasma processing of the substrate is a plasma processing for forming Though Silicon Vias (TSVs).

An antenna assembly and a plasma processing chamber including the same according to the present invention can maintain the constant temperature of a dielectric window through the inductive antenna, the heat conductive member, and the heating plate to which cooling water is supplied during the repetitive substrate treatment process and substrate replacement process and thereby increase the substrate treatment efficiencies. Further, the plasma processing chamber can support the dielectric window more effectively and more strongly through the tilted support surface of the side ring, and can improve the maintenance by allowing the gas manifold and the top nozzle to have screw coupling configurations in between the metal ring gaskets.

### BRIEF DESCRIPTION OF THE DRAWINGS

To enable persons skilled in the art to fully understand the objectives, features, and advantages of the present invention, the present invention is hereunder illustrated with specific embodiments in conjunction with the accompanying drawings, in which:

FIG. 1 is a sectional view of a plasma processing chamber according to one illustrative embodiment of the present invention.

FIG. 2 is an enlarged sectional view showing a tope nozzle and a gas manifold.

FIG. 3 is an enlarged sectional view showing a coupling configuration of a dielectric window and a side ring for supporting an antenna assembly.

### DETAILED DESCRIPTION OF THE PREFERRED EMBODIMENTS

The present invention now will be described more fully hereinafter with reference to the accompanying drawings, in which some, but not all, embodiments of the invention are shown. Indeed, this invention may be embodied in many different forms and should not be construed as limited to the embodiments set forth herein; rather, these embodiments are provided so that this disclosure will satisfy applicable legal requirements. Like numbers refer to like elements throughout.

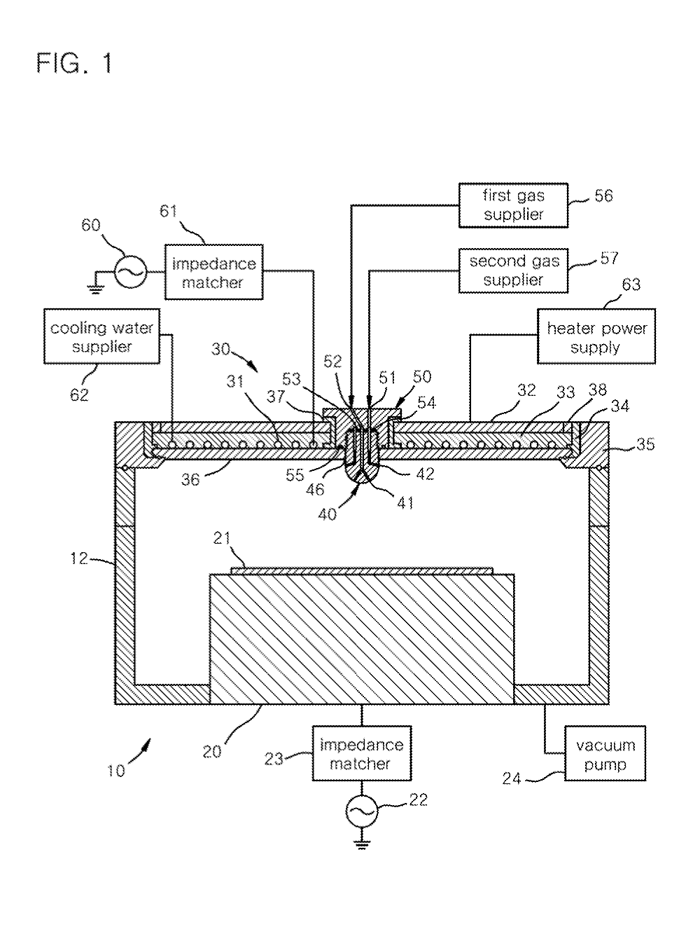

FIG. 1 is a sectional view of a plasma processing chamber according to one preferred embodiment of the present invention.

Referring to FIG. 1, the plasma processing chamber 10 according to a preferred embodiment of the present invention comprises a chamber body 12 and an antenna assembly 30 arranged thereon. The chamber body 12 has a substrate support 20 on which a substrate 21 to be processed is placed. In a ceiling part of the chamber body 12 in upper part of the substrate support 20, a dielectric window 36 of the antenna assembly 30 is placed. The antenna assembly 30 has a dielectric window 36 forming a ceiling of the chamber body and an inductive antenna 31 thereon. The inductive antenna 31 is electrically connected to a main power supply 60 through an impedance matcher 61.

The inductive antenna 31 has a tube structure in hollow form, and is physically connected to a cooling water supplier 62. A heating plate 32 is arranged in upper part of the inductive antenna 31. The heating plate 32 is electrically connected to a heater power supply 63. A heat conductive member 33 is arranged in a space between the dielectric window 36 and the heating plate 33. The heat conductive member 33 comprises thermal conductive silicon, but other alternatives may be applied thereto. The heat conductive member 33 is filled in a space between the dielectric window 36 and the heating plate 33 to contact all of the inductive antenna 31, the dielectric window 36 and the heating plate 32.

The substrate support 20 is electrically connected to a biased power supply 22 through the impedance matcher 23. Although not illustrated in the figure, the substrate support 20 comprises an electro static chuck, a lift pin for moving up and down the substrate 21 to be processed, and an operating module therefore. Further, a discharge baffle and a vacuum pump 24 are arranged in a lower part of the chamber body 12.

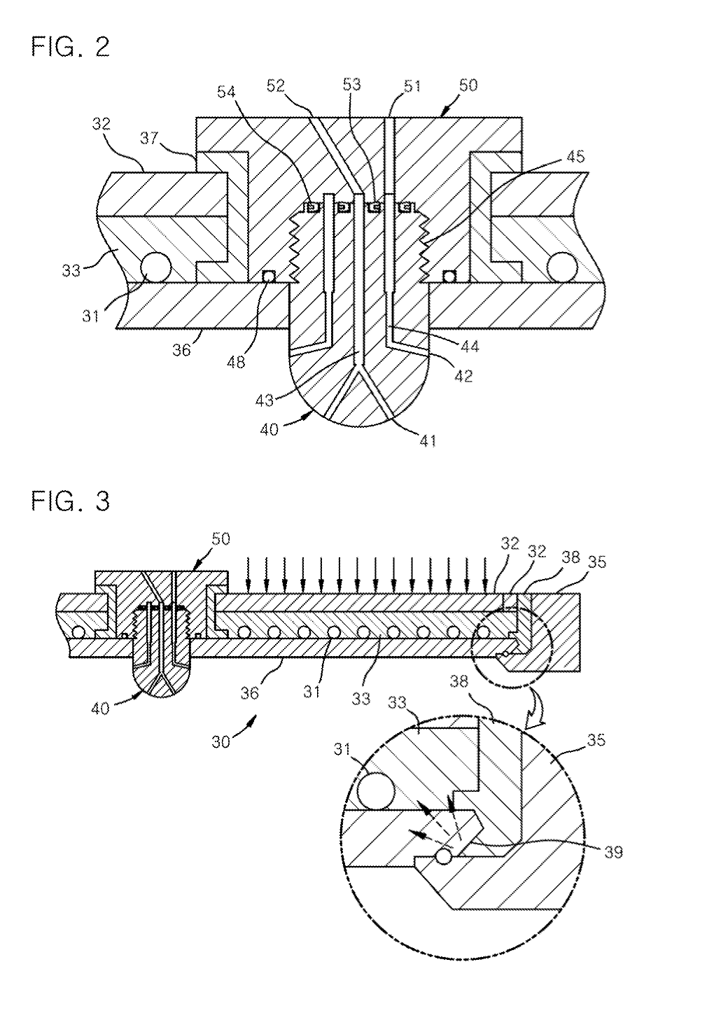

FIG. 2 is an enlarged sectional view showing a tope nozzle and a gas manifold.

Referring to FIG. 2, an opening 46 for housing a top nozzle 40 are formed in a middle part of the dielectric window 36. In upper part of the dielectric window 36, a gas manifold 50 arranged in the opening 46 is tightly connected to the dielectric window 36, with the vacuum insulation ring 55 neighbored. The top nozzle 40 is coupled with the gas manifold 50 through the opening 46. Screw threads 45 are formed on top of the top nozzle 40, and the configurations screw coupled therewith are formed in an inner part of the gas manifold 50. The lower part of the top nozzle 40 is protruded in a concave dome-like form downward from the dielectric window 36. The middle part of the protruded dome-like form of the top nozzle 40 has a plurality of middle spray holes 41 spraying gases toward the middle area of the substrate support 20, and the outer part thereof has a plurality of outer spray holes 42 spraying gases toward the outer area of the substrate support 20. A first gas channel 43 connected to the plurality of middle spray holes 41, and a second gas channel 44 connected to the plurality of outer spray holes 42 are formed in the top nozzle 40 and the gas manifold 50. A first gas inlet 51 of the gas manifold 50 is connected to the first gas channel 43, and a second gas inlet 52 thereof is connected to the second gas channel 44. The first gas inlet 51 is connected to a first gas supplier 56, and the second gas inlet 52 is connected to a second gas supplier 57. Since the top nozzle 40 and the gas manifold 50 have a screw coupling structure, their mounting and separating/combining are facilitated to make easier the replacement of the top nozzle 40.

Two metal ring gaskets 53, 54 are installed into the place where the gas manifold 50 and the top nozzle 40 are contacted. One of the metal ring gaskets 53 is placed between the first gas channel 43 and the second gas channel 44, and the other of the metal ring gaskets 54 is placed between the second gas channel 44 and the outer thereof. Thus, the gases supplied to the first gas channel 43 and the gases supplied to the second gas channel 44 are not to be mixed together, while not leaked to the environment. In particular, since 0-ring made of rubber is not used, but the metal ring gaskets 53, 54 made of metal are used between the gas manifold 50 and the top nozzle 40, it gives excellent durability and semi-permanent use, thereby improving the maintenance efficiency.

FIG. 3 is an enlarged sectional view showing a coupling configuration of a dielectric window and a side ring for supporting an antenna assembly.

Referring now to FIG. 3, a plasma processing chamber according to a preferred embodiment of the present invention comprises a side ring 34 and an outer support ring 35 for supporting the antenna assembly 30 at upper part of the chamber body 12. The side ring 34 may have a coupling structure of three to five pieces. In particular, the side ring 38 has a tilted support surface 39, where the part neighboring with the dielectric window 36 is inclined outward. When the inner space of the chamber body 12 is under low pressure or vacuum state below the atmospheric pressure, the tilted support surface 39 of the side ring 38 may effectively disperse the forced atmospheric pressure from the top of the antenna assembly 30 and prevents the dielectric window 36 from damaging or broken.

Again, referring to FIG. 1, the plasma processing chamber 10 according to a preferred embodiment of the present invention can maintain a constant thermal state in conducting a plasma treatment process for the substrate 21 to be treated, and thus improve the substrate processing efficiency.

In the substrate treatment process, process gases supplied from a first gas supplier 56 and a second gas supplier 57 are injected through a first and a second gas channel 43, 44 of the gas manifold 50. The process gases injected through the first and the second gas channel 43, 44 are sprayed into the chamber body 12 through the middle spray holes 41 and the outer spray holes 42 of the top nozzle 40. The radio frequency supplied from the main power supply 60 is supplied to the inductive antenna 31 through the impedance matcher 61. Once the inductive antenna 31 is operated due to the supply of the radio frequency power, an induced electromotive force is supplied to the chamber body 12, the process gases are then ionized, and consequently plasmas are generated. The substrate treatment process for the substrate 21 to be treated is conducted by the plasmas thus generated. The substrate treatment process is one of various semiconductor fabrication processes. For example, the substrate treatment process may be that for forming TSVs in the substrate 21 to be treated.

Particularly, the plasma processing chamber of the present invention is very useful in conducting the TSV process. The TSV process generally forms the TSVs on the substrate through the repetitive etching and deposition processes, wherein constant temperature is required for the dielectric window. Thereby, the plasma processing chamber of the present invention improves the process reproducibility by maintaining the dielectric window at constant temperature in the TSV process.

When the plasmas are generated in the chamber body 12 by the operation of the inductive antenna 31, the dielectric window 36 is heated, and then the temperature rises. In such case, the heat transfer between the cooling water flowing through the inductive antenna 31 and the inner part thereof and the thermal conductive member 33 prevents the overheating of the dielectric window 36, and accomplishes a uniform temperature distribution. Thus, it prevents the dielectric window 36 from damaging due to the disuniform temperature rises in the dielectric window 36.

After completing the plasma treatment process for the substrate 21, if the plasmas are switched off, then the substrate replacement process is conducted. In this case, since the dielectric window 36 may be cooled due to the switch-off of the plasmas, a heating plate 32 is operated.

When the heating plate 32 is operated, heat is uniformly transferred through the thermal conductive member 33 to the dielectric window 36, while it prevents the dielectric window 36 from cooling and helps to maintain a constant temperature. After the plasmas' switch-off, if the heated dielectric window 36 is merely cooled, polymers may be deposited on a lower part of the dielectric window 31 in the chamber body 12. The deposition of such polymers results in negative effects, such as acting as particles, in the subsequent process.

However, the plasma processing chamber 10 of the present invention conducts a uniform heat conduction between the inductive antenna 31, and the dielectric window 36, and the heat conduction between the heating plate 32, and the dielectric window 36 through the thermal conductive member of the antenna assembly 30 in the course of the repetitive substrate treatment process and the substrate replacement process. In this connection, the dielectric window 36 has a constant temperature and a uniform heat distribution during the repetitive substrate treatment process and substrate replacement process. Accordingly, the deposition of polymers on the dielectric window 36 may be prevented as temperature varies.

The foregoing embodiments of an antenna assembly and a plasma processing chamber comprising the same according to the present invention are illustrative, not limiting thereto. The present invention is applicable to an antenna assembly and a plasma processing chamber comprising the same having different purposes.

Features of the above-described preferred embodiments and the modifications thereof may be combined appropriately as long as no conflict arises.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A plasma processing chamber, comprising:
a chamber body having a substrate support on which the substrate to be processed is placed;
a dielectric window forming a ceiling of the chamber body;
an inductive antenna set on a upper part of the dielectric window and configured to supply an electromotive force generating plasmas into the chamber body;
a cooling water supplier configured to supply cooling water into the inductive antenna;
a heating plate set on a upper part of the inductive antenna; and
a heat conductive member filled in a space between the heating plate and the dielectric window to contact the heating plate, the inductive antenna and the dielectric window,
wherein the heat conductive member makes the dielectric window to have a uniform heat distribution through the heat conduction between the inductive antenna and the dielectric window, and the heat conduction between the heating plate and the dielectric window.

2. The plasma processing chamber of claim 1, wherein the heat conductive member comprises thermal conductive silicon.

3. The plasma processing chamber of claim 1, further comprising:
an opening set in the middle part of the dielectric window to supply a gas into the chamber body;
a gas manifold arranged at an opening in a upper part of the dielectric window; and
a top nozzle coupled with the gas manifold through the opening.

4. The plasma processing chamber of claim 3, wherein the top nozzle comprises a plurality of middle spray holes spraying gases toward the middle area of the substrate support, and a plurality of outer spray holes spraying gases toward the outer area of the substrate support, and wherein the gas manifold and the top nozzle comprise a first gas channel connected to the plurality of middle spray holes and a second gas channel connected to the plurality of outer spray holes.

5. The plasma processing chamber of claim 3, further comprising:
at least one metal ring gasket set on the contact site of the gas manifold and the top nozzle.

6. The plasma processing chamber of claim 3, wherein the top nozzle comprises screw threads for coupling with the gas manifold.

7. The plasma processing chamber of claim 1, further comprising a side ring supporting the dielectric window in upper part of the chamber body,
wherein the side ring comprises a tilted support surface inclined outward from the neighboring dielectric window.

8. The plasma processing chamber of claim 1, wherein the plasma processing of the substrate is plasma processing forming Though Silicon Vias (TSVs).
